(19) United States
(12) Patent Application Publication
(10) Pub. No.: US 2010/0270653 A1
(43) Pub. Date: Oct. 28, 2010

(54) CRYSTALLINE THIN-FILM PHOTOVOLTAIC STRUCTURES AND METHODS FOR FORMING THE SAME

(76) Inventors: Christopher Leitz, Watertown, MA (US); Christopher J. Vineis, Watertown, MA (US); Leslie G. Fritzemeier, Lexington, MA (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/765,232

(22) Filed: Apr. 22, 2010

Related U.S. Application Data
(60) Provisional application No. 61/172,397, filed on Apr. 24, 2009.

(51) Int. Cl. H01L 29/06; B32B 17/06; B32B 15/04; B32B 18/00; B32B 15/01; H01L 21/20

(52) U.S. Cl. 257/618; 428/433; 428/432; 428/450; 428/446; 428/469; 428/686; 428/434; 438/478; 257/E29.005; 257/E21.09

(57) ABSTRACT

Methods for forming semiconductor devices include providing a textured template, forming a buffer layer over the textured template, forming a substrate layer over the buffer layer, removing the textured template, thereby exposing a surface of the buffer layer, removing oxide from the exposed surface of the buffer layer, and forming a semiconductor layer over the exposed surface of the buffer layer.

### CROSS-REFERENCE TO RELATED APPLICATION

This application claims priority to and the benefit of, and incorporates herein by reference in its entirety, U.S. Provisional Patent Application No. 61/172,397, which was filed on Apr. 24, 2009.

### TECHNICAL FIELD

In various embodiments, the present invention relates to photovoltaic structures and devices, and in particular to thin-film photovoltaics.

### BACKGROUND

Both the alternative-energy and flat-panel display markets have a need for high-quality, flexible substrates on which to produce highly crystalline semiconductor thin films.

The current solar cell (i.e., photovoltaic) market relies on technology that has been essentially unchanged for decades. Over 90% of the market is served by crystalline silicon (Si), either single-crystal or polycrystalline, with average conversion efficiencies of 12-20%. The costs of crystalline Si devices are high due to high-cost production methods and high demand for the raw materials in competition with the semiconductor electronics industry. Si devices must also be quite thick to achieve these efficiencies, consuming significant quantities of material. The remaining 10% of the market is served largely by thin-film structures based on amorphous Si, CdTe, or copper-indium-gallium-selenide (“CIGS”) that are cheaper to produce but have energy conversion efficiencies below 10%. Amorphous Si efficiencies also degrade with time.

Higher conversion efficiencies, over 30%, have been demonstrated for thin film multi-junction devices based on III-V semiconductors such as GaAs. However, their production costs are very high since these devices are most advantageously grown on single-crystal germanium (Ge) or GaAs wafers costing over $10,000 per square meter.

Emerging low-cost photovoltaic technologies include ribbon-grown Si, polymeric/organic films, and nanotechnology-based approaches. None of these new solutions fully addresses the market needs for increased production volume, increased efficiency, and lower cost per watt generated.

A useful substrate for the growth of high efficiency semiconductor films (e.g., III-V semiconductor films) preferably enables the growth of low-defect films (similar to those formed on single-crystal wafers) but at much lower cost and with higher area. Flexibility is a useful attribute. The substrate is also preferably chemically compatible with both the semiconductor material and with the semiconductor process environment. These demanding attributes restrict the number of materials that may effectively be used for this application.

The ability to produce polycrystalline metals with crystallographic orientation (e.g., “biaxial texture”) approaching single-crystal quality in pure metals has been known since the 1940's. Practical applications of such texture control have included the production of aluminum sheet with textures that enhance the production of cans. Most commercial uses of sheet materials avoid texture, however, because the properties of sheet materials are more isotropic in its absence.

Face-centered cubic (fcc) metals, some body-centered cubic (bcc) metals, and some alloys based on fcc metals may be useful as substrate materials, as they may be biaxially textured using well-known rolling-deformation and annealing processes. A well-known texture in fcc metals and alloys is the “cube texture,” in which the c-axis of each of the substrate grains is substantially perpendicular to the substrate surface, and the a-axes align primarily along a length direction. Under controlled rolling and annealing processes, these deformation-textured metals may possess biaxial texture approaching that of single crystals.

Nickel (Ni) is one fcc metal that may be made into thin foils with a well-defined cube texture using a rolling and annealing process. Prior work has shown that oxide intermediate layers may be deposited on a biaxially textured Ni surface using conditions under which nickel oxide is not stable, but where the intermediate layer (for example, CeO₂ or Y₂O₃) is stable, allowing the oxide to inherit the texture of the underlying Ni foil, i.e., form epitaxially thereon. The high-purity Ni required to achieve good biaxial texture is expensive and Ni is mechanically weak following the typical annealing heat treatment used to form the cube texture.

For these reasons, Ni alloys and other alloys have been developed to make stronger, non-magnetic biaxially textured foils. These alloys often contain alloying elements such as tungsten (W), molybdenum (Mo), vanadium (V), or chromium (Cr) in small controlled amounts. Relatively pure copper (Cu) may also be processed to produce a high-quality cube texture. Commercial grades of Cu with relatively low oxygen content and relatively low content of substitutional and interstitial elements have been of particular utility. In addition, prior work has shown that a wide range of Ni—Cu alloys may also be processed to produce high-quality cube textures.

Epitaxial films of other materials such as metals, oxides and nitrides can be grown on the biaxially textured foil. As used herein, “epitaxial” means that the crystallographic orientation of the deposited film is derived from and directly related to the crystallographic orientation of the underlying template.

Unfortunately, the existing deformation-textured foil approach is frequently not commercially viable for the deposition of semiconducting films necessary for high-performance optical and photovoltaic devices, e.g., Si, Ge, GaAs, InP, and related alloys and compounds. One promising approach utilizing Cu or Cu—Ni alloy textured foils is described in U.S. Patent Application Publication No. 2007/0044832A1, the entire disclosure of which is incorporated by reference herein. However, such foils may be incompatible with conventional semiconductor processes. Both Cu and Ni form arsenide and silicide phases when exposed to As- or Si-containing gases at typical processing temperatures above approximately 350° C. The formation of these phases causes a significant increase in volume, embrittles the foils, and renders the foils largely unusable for subsequent processing and for most applications.

Thus, while considerable progress has been made in the use of biaxially textured foils for superconductor applications, there is a need for processes and structures for non-superconductor materials and applications such as optical devices, optoelectronic devices, and photovoltaics.

### SUMMARY

The foregoing limitations of conventional thin-film photovoltaic platforms and fabrication processes are herein addressed by removing a highly textured template layer after a buffer layer has “inherited” a texture therefrom but before the formation of semiconductor layers. The template layer is thereby utilized to create a texture suitable for the subsequent fabrication of high-quality semiconductor materials and devices, but is removed before exposure to processes tending to embrittle the template layer.

In an aspect, embodiments of the invention feature a method for forming a semiconductor device. A textured template (which may be a polycrystalline metal) is provided, and a buffer layer (which may also be a polycrystalline metal) is formed thereover. A substrate layer is formed over the buffer layer, and the textured template is removed, thereby exposing a surface of the buffer layer (which may be at least partially oxidized). Oxide is removed from the exposed surface of the buffer layer, and a semiconductor layer is formed over the exposed surface of the buffer layer.

Embodiments of the invention may include one or more of the following, in any of a variety of combinations. The buffer layer may inherit the texture of the textured template during formation of the buffer layer. The oxide that is removed from the exposed surface of the buffer layer may include or consist essentially of a chemical oxide formed during removal of the textured template. After removal of the chemical oxide, a native oxide may form over the exposed surface of the buffer layer prior to formation of the semiconductor layer. The native oxide may have a non-zero thickness less than approximately four monolayers. Forming the semiconductor layer may include or consist essentially of epitaxial deposition of the semiconductor layer through at least one pinhole in the native oxide. The semiconductor layer may be substantially single-crystalline after formation. Removing the oxide and forming the semiconductor layer may be performed without exposure to air therebetween.

The semiconductor layer may include or consist essentially of Si, Ge, and/or a III-V material (e.g., GaAs or InGaAs). The coefficient of thermal expansion of the substrate layer may substantially match the coefficient of thermal expansion of the semiconductor layer. The buffer layer may include or consist essentially of Cr and/or a nitride. The textured template may include or consist essentially of Cu, Ni, and/or a Cu—Ni alloy. The semiconductor layer may include or consist essentially of a p-n junction and/or a p-i-n junction.

A semiconductor device may be formed on the semiconductor layer. The semiconductor device may include or consist essentially of GaAs, AlGaAs, InGaP, InGaAsN, InGaAsP, InP, AlInAs, and/or InGaAs. The semiconductor device may include or consist essentially of a photovoltaic cell, a light-emitting diode, and/or a laser.

In another aspect, embodiments of the invention feature a method for forming a semiconductor device. A textured template (which may be a polycrystalline metal) is provided, and a buffer layer (which may also be a polycrystalline metal) is formed over the textured template, the buffer layer inheriting the texture of the textured template. A diffusion barrier is formed over the buffer layer, the diffusion barrier inheriting the texture of the textured template, and a substrate layer is formed over the diffusion barrier. The textured template and the buffer layer are removed, thereby exposing a surface of the diffusion barrier. A second buffer layer (which may be a polycrystalline metal) is formed over the exposed surface of the diffusion barrier, and a semiconductor layer is formed over the second buffer layer.

Forming the buffer layer, diffusion barrier, substrate layer, semiconductor layer, and/or second buffer layer may include or consist essentially of epitaxial deposition. The diffusion barrier may include or consist essentially of W. The semiconductor layer may include or consist essentially of Si, Ge, and/or a III-V material (e.g., GaAs or InGaAs). The coefficient of thermal expansion of the substrate layer may substantially match the coefficient of thermal expansion of the semiconductor layer. The buffer layer and/or the second buffer layer may include or consist essentially of Cr and/or a nitride. The textured template may include or consist essentially of Cu, Ni, and/or a Cu—Ni alloy. The semiconductor layer may include or consist essentially of a p-n junction and/or a p-i-n junction.

A semiconductor device may be formed on the semiconductor layer. The semiconductor device may include or consist essentially of GaAs, AlGaAs, InGaP, InGaAsN, InGaAsP, InP, AlInAs, and/or InGaAs. The semiconductor device may include or consist essentially of a photovoltaic cell, a light-emitting diode, and/or a laser.

In yet another aspect, embodiments of the invention feature a method for forming a semiconductor device. A textured template (which may be a polycrystalline metal) is provided, and a buffer layer (which may also be a polycrystalline metal) is formed over the textured template, the buffer layer inheriting the texture of the textured template. An oxidation-resistant layer is formed over the buffer layer, the oxidation-resistant layer inheriting the texture of the textured template, and a substrate layer is formed over the oxidation-resistant layer. The textured template and the buffer layer are removed, thereby exposing a surface of the oxidation-resistant layer, and a semiconductor layer is formed over the exposed surface of the oxidation-resistant layer.

A second buffer layer (which may be a polycrystalline metal) may be formed over the exposed surface of the oxidation-resistant layer prior to forming the semiconductor layer, the second buffer layer inheriting the texture of the textured template. The second buffer layer may include or consist essentially of Cu and/or Fe. The oxidation-resistant layer may have a free energy of oxide formation greater than the free energy of oxide formation of the buffer layer. The oxidation-resistant layer may include or consist essentially of at least one noble metal, e.g., Pd, Rh, Pt, and/or Ir. After removal of the textured template and the buffer layer, the exposed surface of the oxidation-resistant layer may be substantially free of oxide. The semiconductor layer may include or consist essentially of Si, Ge, and/or a III-V material (e.g., GaAs or InGaAs). The coefficient of thermal expansion of the substrate layer may substantially match the coefficient of thermal expansion of the semiconductor layer. The buffer layer may include or consist essentially of Cr and/or a nitride. The textured template may include or consist essentially of Cu, Ni, and/or a Cu—Ni alloy. The semiconductor layer may include or consist essentially of a p-n junction and/or a p-i-n junction.

A semiconductor device may be formed on the semiconductor layer. The semiconductor device may include or consist essentially of GaAs, AlGaAs, InGaP, InGaAsN, InGaAsP, InP, AlInAs, and/or InGaAs. The semiconductor device may include or consist essentially of a photovoltaic cell, a light-emitting diode, and/or a laser.

In a further aspect, embodiments of the invention feature a method for forming a semiconductor device. A textured template (which may be a polycrystalline metal) is provided, and an etch-stop layer is formed over the textured template, the etch-stop layer inheriting the texture of the textured template. A diffusion barrier is formed over the etch-stop layer, and a substrate layer is formed over the diffusion barrier. The textured template is removed, thereby exposing a surface of the etch-stop layer, and a semiconductor layer is formed over the exposed surface of the etch-stop layer.

The etch-stop layer may include or consist essentially of a noble metal, e.g., Ir, and/or an epitaxial oxide. A buffer layer (which may be a polycrystalline metal) may be formed over the exposed surface of the etch-stop layer prior to forming the semiconductor layer, the buffer layer inheriting the texture of the textured template. The buffer layer may include or consist essentially of Cr and/or Fe. The semiconductor layer may include or consist essentially of Si, Ge, and/or a III-V material (e.g., GaAs or InGaAs). The coefficient of thermal expansion of the substrate layer may substantially match the coefficient of thermal expansion of the semiconductor layer. The textured template may include or consist essentially of Cu, Ni, and/or a Cu—Ni alloy. The semiconductor layer may include or consist essentially of a p-n junction and/or a p-i-n junction.

A semiconductor device may be formed on the semiconductor layer. The semiconductor device may include or consist essentially of GaAs, AlGaAs, InGaP, InGaAsN, InGaAsP, InP, AlInAs, and/or InGaAs. The semiconductor device may include or consist essentially of a photovoltaic cell, a light-emitting diode, and/or a laser.

In yet another aspect, embodiments of the invention feature a method for forming a semiconductor device. A textured template (which may be a polycrystalline metal) is provided, and an epitaxial oxidation-resistant layer is formed over the textured template. An epitaxial lift-off layer is formed over the oxidation-resistant layer, and an epitaxial semiconductor layer is formed over the lift-off layer. A substrate layer is formed over the semiconductor layer, and the lift-off layer is removed, thereby exposing a surface of the semiconductor layer.

The lift-off layer may be substantially water-soluble, and may include or consist essentially of an ionic salt, e.g., CaF₂ and/or NaCl. After removal of the lift-off layer, the textured template and the oxidation-resistant layer may be reused by depositing a second lift-off layer over the oxidation-resistant layer. The oxidation-resistant material may include or consist essentially of a noble metal, e.g., Pd and/or Ir. The semiconductor layer may include or consist essentially of Si, Ge, and/or a III-V material (e.g., GaAs or InGaAs). The coefficient of thermal expansion of the substrate layer may substantially match the coefficient of thermal expansion of the semiconductor layer. The textured template may include or consist essentially of Cu, Ni, and/or a Cu—Ni alloy. The semiconductor layer may include or consist essentially of a p-n junction and/or a p-i-n junction. A diffusion barrier may be formed over the semiconductor layer before forming the substrate layer. The diffusion barrier may include or consist essentially of W.

A semiconductor device may be formed on the semiconductor layer after removal of the lift-off layer. The semiconductor device may include or consist essentially of GaAs, AlGaAs, InGaP, InGaAsN, InGaAsP, InP, AlInAs, and/or InGaAs. The semiconductor device may include or consist essentially of a photovoltaic cell, a light-emitting diode, and/or a laser.

In another aspect, embodiments of the invention feature a semiconductor structure including or consisting essentially of a substantially untextured substrate layer, a textured diffusion barrier disposed over the substrate layer, a textured buffer layer disposed over the textured diffusion barrier, and a semiconductor layer (which may be textured and/or polycrystalline) disposed over the textured buffer layer.

The grain size of the textured buffer layer may be greater than approximately 25 μm. The textured buffer layer (which may be polycrystalline) may include or consist essentially of a metal (e.g., Cr) or a metal alloy. The textured diffusion barrier (which may be polycrystalline) may include or consist essentially of a metal (e.g., W and/or Re) or a metal alloy. The substrate layer may include or consist essentially of W, Mo, a metal alloy, a ceramic, and/or a glass. The coefficient of thermal expansion of the substrate layer may substantially match the coefficient of thermal expansion of the semiconductor layer. The semiconductor structure may include a semiconductor device disposed over the semiconductor layer. The semiconductor device may include or consist essentially of GaAs, AlGaAs, InGaP, InGaAsN, InGaAsP, InP, AlInAs, and/or InGaAs. The semiconductor device may include or consist essentially of a photovoltaic cell, a light-emitting diode, and/or a laser.

In a further aspect, embodiments of the invention feature a semiconductor structure including or consisting essentially of a substantially untextured substrate layer, a textured buffer layer disposed over the substrate layer, a native oxide layer disposed over the textured buffer layer, and a semiconductor layer disposed over the native oxide layer.

The native oxide layer may have a non-zero thickness less than approximately four monolayers. The semiconductor layer may be substantially single-crystalline, and may extend to the textured buffer layers through at least one pinhole in the native oxide layer. The grain size of the textured buffer layer may be greater than approximately 25 μm. The textured buffer layer (which may be polycrystalline) may include or consist essentially of a metal (e.g., Cr) or a metal alloy. A diffusion barrier (which may be textured and/or polycrystalline) may be disposed between the substrate layer and the textured buffer layer. The diffusion barrier may include or consist essentially of a metal (e.g., W and/or Re), a metal alloy, an oxide, and/or a nitride. An insulator layer, which may include or consist essentially of an oxide, may be disposed between the substrate layer and the textured buffer layer. The substrate layer may include or consist essentially of W, Mo, a metal alloy, a ceramic, and/or a glass. The coefficient of thermal expansion of the substrate layer may substantially match the coefficient of thermal expansion of the semiconductor layer. The semiconductor structure may include a semiconductor device disposed over the semiconductor layer. The semiconductor device may include or consist essentially of GaAs, AlGaAs, InGaP, InGaAsN, InGaAsP, InP, AlInAs, and/or InGaAs. The semiconductor device may include or consist essentially of a photovoltaic cell, a light-emitting diode, and/or a laser.

In another aspect, embodiments of the invention feature a structure including or consisting essentially of a textured template, an etch-stop layer disposed over the textured template, and a substantially untextured substrate layer disposed over the etch-stop layer, wherein there is substantially no interdiffusion between the textured template and the etch-stop layer. The textured template includes or consists essentially of a first metal. The etch-stop layer includes or consists essentially of an oxide and/or a second metal different from the first metal. The substrate layer includes or consists essentially of a ceramic, a glass, and/or a third metal different from both the first and second metals.

The etch-stop layer may include or consist essentially of a noble metal, e.g., Pd and/or Ir. The texture of the etch-stop layer may substantially match the texture of the textured template.

In an aspect, embodiments of the invention feature a structure including or consisting essentially of a textured template, an epitaxial oxidation-resistant layer disposed over the textured template, an epitaxial lift-off layer disposed over the oxidation-resistant layer, an epitaxial semiconductor layer disposed over the lift-off layer, and a substantially untextured substrate layer disposed over the semiconductor layer.

The lift-off layer may be substantially water-soluble, and/or may include or consist essentially of an ionic salt, e.g., CaF₂ and/or NaCl. The grain size of the oxidation-resistant layer may be greater than approximately 25 μm. The oxidation-resistant layer may include or consist essentially of a noble metal, e.g., Pd and/or Ir. The structure may include a diffusion barrier disposed between the substrate layer and the semiconductor layer. The diffusion barrier may include or consist essentially of a metal (e.g., W and/or Re), a metal alloy, an oxide, and/or a nitride. The substrate layer may include or consist essentially of W, Mo, a metal alloy, a ceramic, and/or a glass. The coefficient of thermal expansion of the substrate layer may substantially match the coefficient of thermal expansion of the semiconductor layer. The semiconductor layer may include or consist essentially of Si, Ge, and/or a III-V material (e.g., GaAs or InGaAs).

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations. As used herein unless otherwise indicated, the term “substantially” means±10%, and in some embodiments, ±5%. Unless otherwise indicated, layers characterized as “textured” are generally polycrystalline with highly oriented grains.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1A is a schematic cross-sectional diagram of an exemplary structure formed on a textured template in accordance with various embodiments of the invention;

FIG. 1B is a schematic diagram of the structure of FIG. 1A after removal of the textured template;

FIGS. 2-4 are schematic diagrams of the structure of FIG. 1B after further deposition and processing in accordance with various embodiments of the invention;

FIG. 5A is a schematic cross-sectional diagram of a structure formed after removal of a textured template in accordance with various embodiments of the invention;

FIG. 5B is a schematic diagram of the structure of FIG. 5A after deposition of various layers;

FIG. 6A is a schematic cross-sectional diagram of an exemplary structure including an oxidation-resistant layer formed on a textured template in accordance with various embodiments of the invention;

FIG. 6B is a schematic diagram of the structure of FIG. 6A after removal of the textured template;

FIG. 7A is a schematic cross-sectional diagram of an exemplary structure including an etch-stop layer formed on a textured template in accordance with various embodiments of the invention;

FIG. 7B is a schematic diagram of the structure of FIG. 7A after removal of the textured template;

FIG. 8A is a schematic cross-sectional diagram of an exemplary structure including a lift-off layer formed on a textured template in accordance with various embodiments of the invention; and

FIG. 8B is a schematic diagram of the structure of FIG. 7A after removal of the lift-off layer.

### DETAILED DESCRIPTION

Templates suitable for use in embodiments of the present invention include crystallographically oriented material layers that are chemically compatible and are lattice-matched with known and anticipated semiconductor materials, in particular with compound semiconductors (e.g., III-V semiconductor materials). “Lattice-matched,” as used herein, refers to layers or materials having relative lattice spacings that allow the epitaxial growth of one layer (e.g., a buffer) on the other (e.g., a template) with a controlled texture and an acceptable level of defects to enable the subsequent integration of high-quality semiconductor materials and/or high-efficiency semiconductor devices. For metallic films, lattice-matching may be within an approximately 10% relative difference in lattice spacing, preferably within approximately 5%, and more preferably within approximately 2%. The lattice spacing may refer to the material's unit-cell lattice constant as it is commonly defined in the art, or to another interatomic spacing that can be defined in reference to the lattice constant. For instance, the lattice constant of a material may be lattice-matched to the lattice spacing defined by the diagonal of a face of a cubic crystal (which is approximately equal to 1.414 times the lattice constant). Furthermore, a material having a lattice constant (or other lattice spacing) that is approximately an integral multiple (again, within approximately 10%, approximately 5%, or approximately 2%) of that of another material may also be considered to be “lattice matched.” For example, a material having a lattice spacing approximately twice that of a second material will achieve approximate lattice registry with every other atom of the second material. The necessary degree of matching may depend on the type of material under consideration. For example, a high-quality semiconductor layer may require closer lattice-matching to an underlying layer than a metal layer deposited on another metal layer. Non-limiting examples of lattice-matching include Cr and palladium (Pd), which are matched to within approximately 8%, as well as the cube-face diagonal of Cr and one-half the cube-face diagonal of Ge, which are matched to within approximately 3%.

“Chemically compatible,” as used herein, means that a material is not reactive with a semiconductor process environment and preferably is not reactive with and does not react with (at least at the processing temperatures contemplated herein) or contaminate a semiconductor material integrated thereon. Further, even if a reaction does occur, a chemically compatible material should not react with a semiconductor to the extent that it degrades the quality or performance of the semiconductor. As one non-limiting example of chemical compatibility, Ge and Cr may react to form a GeCr compound, but this compound is stable and does not affect the performance of either the remaining unreacted Ge or other semiconductors formed atop the unreacted Ge.

As used herein, “texture” refers to a defined crystallographic orientation that extends throughout the thickness of a layer of material, as opposed to mere topology of a surface that does not extend through an entire thickness. As used herein, “biaxial” refers to crystal grains in the substrate or film in close alignment with both a direction perpendicular to the surface of the film and a direction in the plane of the film. Biaxial texturing allows for the production of a low volume of point and line defects in a semiconducting film, and minimizes the carrier-trapping effects of high-angle grain boundaries. This enables very high current densities in these films at typical device operating conditions. “Untextured,” as utilized herein refers to materials that lack texture (as defined above), e.g., materials having randomly oriented crystal grains or that are amorphous. “Substantially untextured” layers may have texture through a small portion of a thickness thereof (e.g., less than approximately 20%, or even less than approximately 10%), but do not exhibit texture through their entire thicknesses. “Epitaxial” layers have crystal structures substantially matching the crystal structure of an adjacent layer, e.g., an underlying substrate on which the epitaxial layer is deposited, and generally do not feature a network of screw dislocations at an interface with the adjacent layer (which may be characteristic of a wafer-bonding process, as such processes typically are not accomplished with perfect registry at the atomic level). Layers described herein formed by deposition on crystalline (i.e., not amorphous) layers are typically epitaxial with respect to such underlying layers unless otherwise indicated.

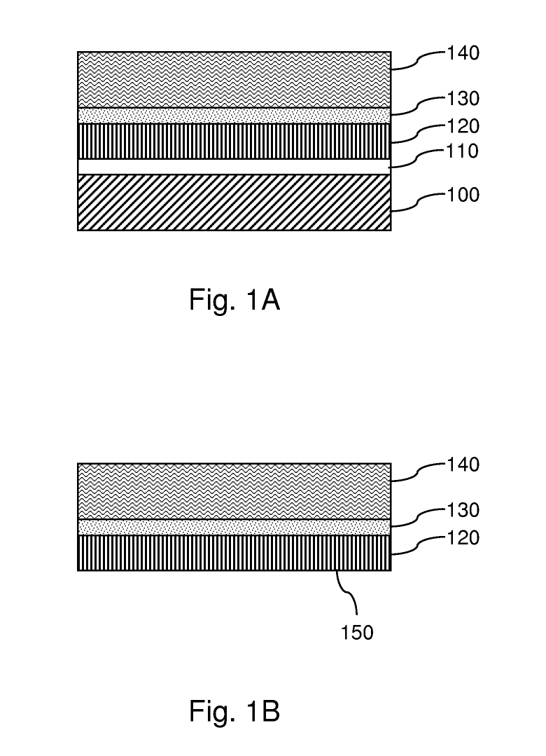

Referring to FIG. 1A, a textured template 100 is provided by, e.g., deformation rolling and annealing processes known in the art. Textured template 100 may be in the form of a thin foil, and may have a thickness between approximately 10 micrometers (μm) and approximately 100 μm, e.g., approximately 25 μm. A surface of textured template 100 may be polished, e.g., to mirror smoothness. Textured template 100 may include or consist essentially of a metal or a metal alloy, e.g., Cu, Ni, a Cu alloy, and/or a Ni alloy, and is generally polycrystalline. Textured template 100 has a defined texture, e.g., a biaxial texture such as a cube texture. Preferably the textured template 100 will exhibit, upon measurement by x-ray diffraction pole figure analysis, a full-width-half-maximum (FWHM) texture spread less than approximately 10 degrees, and preferably less than approximately 5 degrees. In some embodiments, textured template 100 has a grain size greater than approximately 25 μm, preferably greater than approximately 50 μm, and even more preferably greater than approximately 100 μm. Textured template 100 may not be chemically compatible with semiconductor materials such as Ge, Si, and III-V semiconductors at typical processing temperatures above approximately 350° C. In certain embodiments, textured template 100 includes or consists essentially of a material that forms H-containing phases, As-containing phases, and/or Si-containing phases at temperatures greater than approximately 350° C. upon exposure to precursors or other materials containing H, As, and/or Si.

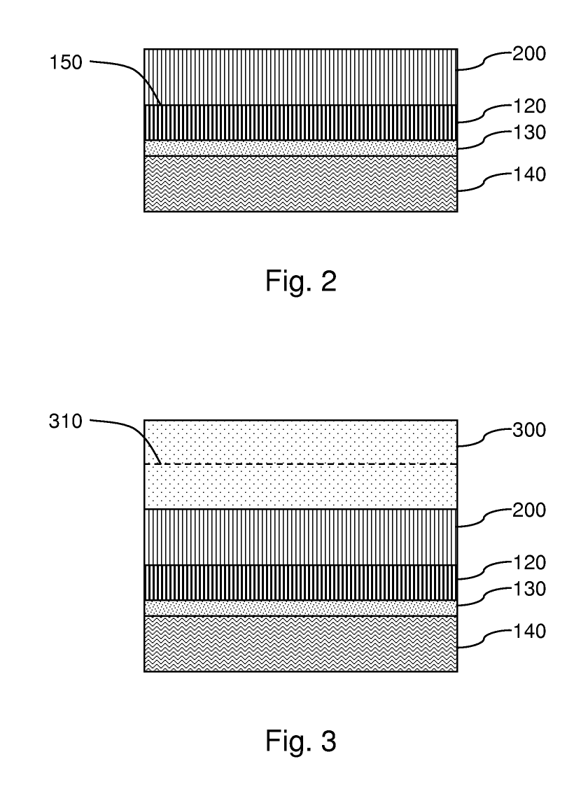

Optionally, a sacrificial layer 110 is formed over textured template 100. Sacrificial layer 110 may include or consist essentially of a metal or a metal alloy, e.g., Pd, platinum (Pt), aluminum (Al), or silver (Ag), or may include or consist essentially of an element or compound enabling improved lattice matching between textured template 100 and buffer layer 120 (described below), e.g., a material having a lattice spacing therebetween. Sacrificial layer 110 is generally polycrystalline, and may be formed by deposition, e.g., evaporation, sputtering, chemical vapor deposition, atomic layer deposition, molecular beam epitaxy, metallorganic deposition, or by electrochemical means such as electroplating (with or without electrodes). During formation, sacrificial layer 110 “inherits” the texture of textured template 100, i.e., forms with such atomic registry as to replicate or improve upon the texture through its thickness. The “inheritance” of an underlying texture may provide superior texture through a thickness of a layer when compared to, e.g., a layer formed via ion-beam assisted deposition on a substantially untextured substrate (while small-range texturing and small grains (i.e., less than 1 μm in size) may develop in such layers, they will generally lack consistent texturing through their entire thicknesses). Textures may also be inherited by layers not adjacent to the originally textured layer (e.g., textured template 100), so long as the texture has been inherited by the intermediate layers therebetween. Similarly, a texture may be inherited even after removal of the original textured layer via inheritance from another layer that had inherited the texture prior to the removal (as described below with reference to FIG. 2). Formation of sacrificial layer 110 may be performed without ion-beam assistance. During subsequent processing of textured template 100, sacrificial layer 110 may substantially react with or diffuse into textured template 100. Sacrificial layer may have a thickness of, e.g., less than approximately 200 nm, e.g., less than approximately 100 nm, or even less than approximately 50 nm.

A buffer layer 120 is formed over textured template 100 and optional sacrificial layer 110. Buffer layer 120 may include or consist essentially of a metal or a metal alloy, e.g., Cr or iron (Fe), or may include or consist essentially of a nitride. Buffer layer 120 may have a thickness of, e.g., between approximately 100 nm and approximately 500 nm, e.g., approximately 200 nm. Buffer layer 120 may be polycrystalline, and may be formed by deposition, e.g., evaporation, sputtering, chemical vapor deposition, atomic layer deposition, molecular beam epitaxy, metallorganic deposition, or by electrochemical means such as electroplating (with or without electrodes). During formation, buffer layer 120 inherits the texture of textured template 100. Buffer layer 120 may be provided without ion-beam assistance. In some embodiments, multiple buffer layers 120 may be formed over textured template 100.

An optional diffusion barrier 130 is formed over buffer layer 120. Diffusion barrier 130 may be formed substantially non-epitaxially and thus be substantially lacking the texture of buffer layer 120 and textured template 100. Diffusion barrier 130 may include or consist essentially of a metal or a metal alloy, e.g., W or rhenium (Re), or may include or consist essentially of a nitride or an oxide, e.g., a compound consisting essentially of oxygen and at least one non-metallic element such as Si. Diffusion barrier 130 prevents substantially all interdiffusion or reaction between substrate layer 140 and semiconductor materials and devices formed over buffer layer 120 (as further described below).

In addition to or instead of diffusion barrier 130, an insulator layer (not shown), e.g., a dielectric or other electrical insulator, may be formed over buffer layer 120. The insulator layer may be amorphous, and may include or consist essentially of an oxide, e.g., a compound consisting essentially of oxygen and at least one non-metallic element such as Si. In an embodiment, the insulator layer may include or consist essentially of a nitride or aluminum oxide. The insulator layer may be formed by deposition, e.g., evaporation, sputtering, chemical vapor deposition, atomic layer deposition, or molecular beam epitaxy, and may be formed without ion-beam assistance. The insulator layer may provide electrical insulation between substrate layer 140 and subsequently formed semiconductor materials and devices (as further described below).

A substrate layer 140 is formed over buffer layer 120 and optional diffusion barrier 130 (and/or the insulator layer, if present). Substrate layer 140 provides structural support to semiconductor materials and devices formed over buffer layer 120 after removal of textured template 100 (as further described below), and is preferably chemically compatible with semiconductor materials such as Ge, Si, and III-V semiconductors at typical processing temperatures above approximately 350° C. In a preferred embodiment, substrate layer 140 includes or consists essentially of a material substantially impervious to formation of H-containing phases, As-containing phases, and/or Si-containing phases at temperatures greater than approximately 350° C. Substrate layer 140 (and, in some embodiments, diffusion barrier 130 and/or the above-described insulator layer) may be formed substantially non-epitaxially and thus be substantially lacking the texture of buffer layer 120 and textured template 100. Therefore, substrate layer 140 may be formed by any method known in the art, e.g., vacuum deposition, chemical vapor deposition, heat lamination, electrodeposition, slurry coating, metallorganic deposition, or lamination. In the case of lamination, the laminating agent such as, for example, a braze alloy or adhesive, should also be chemically compatible and thermally stable with any subsequent semiconductor processes. In an embodiment, substrate layer 140 is formed by electron-beam evaporation at a temperature greater than approximately 900° C. Substrate layer 140 may include or consist essentially of a composite, a ceramic (e.g., alumina and/or zirconia), a glass, a metal alloy (e.g., a Fe—Ni—Co alloy such as KOVAR™), or a metal, e.g., W, and/or Mo. In an embodiment, substrate layer 140 includes or consists essentially of a metal coated with a thicker ceramic material for additional structural support. In various embodiments, substrate layer 140 is flexible and thus capable of being manipulated into non-planar configurations. Substrate layer 140 may be substantially electrically conductive, enabling it to function as a contact, e.g., a back contact, for a subsequently formed semiconductor device. Substrate layer 140 may have a thickness of, e.g., between approximately 1 μm and approximately 0.5 mm.

Referring to FIG. 1B, textured template 100 (and optional sacrificial layer 110, if present) is removed, exposing surface 150 of buffer layer 120. Textured template 100 may be removed by a selective process and/or with end-point monitoring. As utilized herein, a selective process will remove substantially all of textured template 100 without adversely affecting surface 150, thereby rendering surface 150 suitable for the subsequent formation of semiconductor materials and/or devices thereon. Suitable selective processes may include, e.g., chemical etching (with, e.g., an acid such as nitric acid), electrochemical etching, plasma etching, ion-beam bombardment, laser ablation, melting, and reverse-bias sputtering. Suitable end-point monitoring methods may include, e.g., surface reflectance, residual-gas analysis, optical-absorption spectroscopy, and other methods known in the art to be capable of detecting the substantially complete removal of textured template 100. Optionally, the exposed surfaces of substrate layer 140 may be protected from damage or removal by a protective layer (not shown) during removal of textured template 100. The texture of buffer layer 120 (inherited from textured template 100), and thus, surface 150, remains substantially unchanged after removal of textured template 100.

Referring to FIG. 2, at least one semiconductor layer 200 is formed over surface 150 of buffer layer 120. Buffer layer 120 and semiconductor layer 200 are preferably lattice-matched and chemically compatible. Semiconductor layer 200 may include or consist essentially of at least one group IV element or compound (e.g., Si, Ge, or SiGe), or a III-V compound (e.g., a compound including a combination of Al, Ga, In, As, P, and/or N), and may be doped (i.e., include n-type and/or p-type dopants). In a preferred embodiment, semiconductor layer 200 includes or consists essentially of at least one of Si, Ge, or InGaAs. Semiconductor layer 200 is generally polycrystalline, and may inherit the texture of buffer layer 120 and may be substantially crystallographically oriented; the orientation may be, e.g., (100), (110), or (111). Semiconductor layer 200 may be formed by deposition, e.g., chemical vapor deposition, atomic layer deposition, molecular beam epitaxy, liquid phase epitaxy, or physical vapor deposition, at a deposition temperature between approximately 25° C. and approximately 700° C. The thickness of semiconductor layer 200 may be between approximately 100 nm and approximately 5 μm, e.g., approximately 2 μm. In an embodiment, semiconductor layer 200 is doped to form a p-n junction and/or a p-i-n junction therein. Such a junction may function as part of a subsequently fabricated semiconductor device (as described further below). Semiconductor layer 200 may include or consist essentially of at least one homojunction or of at least one heterojunction (incorporating multiple semiconductor materials, e.g., forming a quantum well of one material “sandwiched” between layers of another material). In an embodiment, semiconductor layer 200 may be graded in composition and/or lattice parameter. For example, semiconductor layer 200 may include a material such as Si₁₋ₓGeₓ or In₁₋ₓGaₓAs in which x varies over the thickness of the layer.

In a preferred embodiment, coefficients of thermal expansion of semiconductor layer 200 (and/or subsequently formed semiconductor materials and devices) and substrate layer 140 are substantially matched over the temperature range at which growth of semiconductor layer 200 and all subsequent steps are performed, thus enabling the fabrication of semiconductor materials and devices substantially free of deleterious residual stresses and/or cracks. According to various embodiments of the invention, substantially matched coefficients of thermal expansion have a relative difference of less than approximately 20%, preferably less than approximately 10-15%, and even more preferably less than approximately 5%. For example, a coefficient of thermal expansion of Mo is approximately 4.8×10⁻⁶/° C. at 25° C., matched to within approximately 15% of that of Ge or GaAs (approximately 5.7×10⁻⁶/° C. at 25° C.).

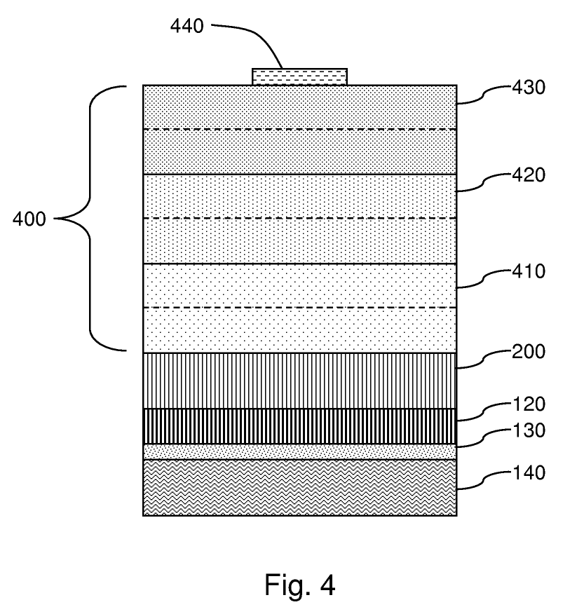

Referring to FIG. 3, in various embodiments of the invention, a semiconductor device 300 is formed over semiconductor layer 200. Semiconductor device 300 may include or consist essentially of a photovoltaic cell (see also, e.g., FIG. 4), a light-emitting diode, a laser, or a display. Semiconductor device 300 may include or consist essentially of a III-V compound (e.g., a compound including a combination of Al, Ga, In, As, P, and/or N), and may be doped (i.e., include n-type and/or p-type dopants). In an embodiment, semiconductor device 300 includes or consists essentially of at least one of GaAs, AlGaAs, InGaP, InGaAsN, InGaAsP, InP, AlInAs, or InGaAs. Semiconductor device 300 may be doped to form at least one p-n junction and/or p-i-n junction. In FIG. 3, boundary 310 represents the approximate boundary between p- and n-type doped regions in a p-n junction or the intrinsic region in a p-i-n junction. Semiconductor device 300 may be lattice-matched to semiconductor layer 200, and may have a texture substantially equal to that of semiconductor layer 200. Semiconductor device 300 may include or consist essentially of at least one homojunction or of at least one heterojunction.

FIG. 4 illustrates a multijunction photovoltaic cell 400 formed over semiconductor layer 200. Cell 400 includes a plurality of p-n or p-i-n junctions; three such junctions 410, 420, 430 are depicted in FIG. 4. Each of the junctions may have a different bandgap; thus, each junction may absorb light of a different wavelength, increasing the overall efficiency of cell 400. The intrinsic layer in a p-i-n junction may decrease dark current of cell 400 (or a junction therein) by substantially preventing the formation of current leakage paths from the p-type doped layer to the n-type doped layer (or vice versa) along grain boundaries in one or more of the layers. The intrinsic layer may also decrease dark current of cell 400 by reducing tunneling (e.g., trap-assisted and/or band-to-band tunneling) of carriers between the p-type doped and n-type doped layers. One or more of the semiconductor materials in cell 400 may be substantially lattice-matched to semiconductor layer 200, and semiconductor layer 200 may include a p-n or p-i-n junction (and thus form an active portion of the device, as mentioned above). A top contact 440, which may include or consist essentially of, e.g., a metal or a transparent conductor (such as indium tin oxide), may be formed to enable electrical contact to cell 400. Substrate layer 140 may function as a back contact to cell 400. In structures containing an optional insulator layer over substrate layer 140, the insulator layer may provide isolation between multiple semiconductor devices 300 and/or cells 400 formed over a common substrate layer 140. Cell 400 (and/or other semiconductor devices 300) may exhibit energy conversion efficiencies greater than approximately 15%, greater than approximately 20%, or even greater than approximately 30% under one-sun terrestrial illumination conditions. The devices may exhibit greater than 80% of the energy conversion efficiencies of substantially similar devices fabricated over single-crystal semiconductor substrates.

The layer and/or device fabrication processes described herein may be practiced in a conventional batch or single-wafer process or by a roll-to-roll continuous or stepwise manufacturing method. The resulting devices may have surface areas greater than approximately 115 cm². Roll-to-roll processes may take place in a continuous system in which each step of the process is performed, or in a series of systems, each of which performing one or more of the steps in the process. A roll-to-roll process (or processes) may include or consist essentially of deposition of sacrificial layer 110, buffer layer 120, diffusion layer 130, and one or more semiconductor layers 200. A roll-to-roll process may also include the removal of textured template 100. Moreover, devices and materials utilized in accordance with embodiments of the present invention may be substantially non-superconducting.

Utilizing a buffer layer 120 including or consisting essentially of Cr (or, in some cases, a nitride) may present particular processing challenges. These challenges may be exacerbated, in some embodiments, by interdiffusion of sacrificial layer 110 and textured template 100 prior to removal thereof. In certain embodiments, these challenges are addressed with additional processing steps and/or the use of alternative materials for buffer layer 120 and/or sacrificial layer 110. Cr has a free energy of oxide formation of approximately −625 kJ/mol, and thus tends to oxidize relatively easily. Certain techniques for the removal of textured template 100 and sacrificial layer 110 utilize oxidants such as acids, and may thus result in an oxide formed on surface 150. Such an oxide may render growth of subsequent layers (such as semiconductor layer 200) difficult or impossible. Thus, in embodiments in which an oxide is formed on surface 150, the oxide is preferably removed by, e.g., in-situ etching or cleaning, immediately prior to the formation of an additional layer on surface 150.

The oxide may be removed from surface 150 by any of several in-situ methods. For example, surface 150 may be heated in a vacuum environment (preferably to a temperature greater than approximately 600° C., and more preferably to a temperature greater than approximately 800° C.) under exposure to molecular hydrogen. In another embodiment, surface 150 may be heated in a vacuum environment under exposure to atomic hydrogen (or another reducing agent) formed, e.g., by a plasma source or filament heater, in order to remove the oxide. In another embodiment, the oxide may be removed by bombarding surface 150 in a vacuum environment with low-energy ions (such as, e.g., Ar) to mill away the oxide. Finally, the oxide may be by reversing the potential in an electroetching system.

In some embodiments, a chemical oxide may be removed from surface 150, but a native oxide of, e.g., Cr, may remain or subsequently form on surface 150. In embodiments in which a native oxide is present, preferably approximately four monolayers or less of the oxide are present on surface 150; a native oxide of such thicknesses may not preclude the epitaxial growth of additional layers on surface 150. In fact, additional layers, such as semiconductor layers, may initially nucleate on surface 150 through one or more pinholes through the native oxide, and during deposition may not only grow vertically but also laterally over the native oxide. In this manner, a layer, e.g., a semiconductor layer, may be deposited over surface 150 in substantially single-crystalline form (rather than the polycrystalline form typical of layers grown on the above-described textured layers). As used herein, a substantially single-crystalline layer may still include defects such as stacking faults, e.g., between regions that nucleated over different portions of surface 150 and coalesced during deposition.

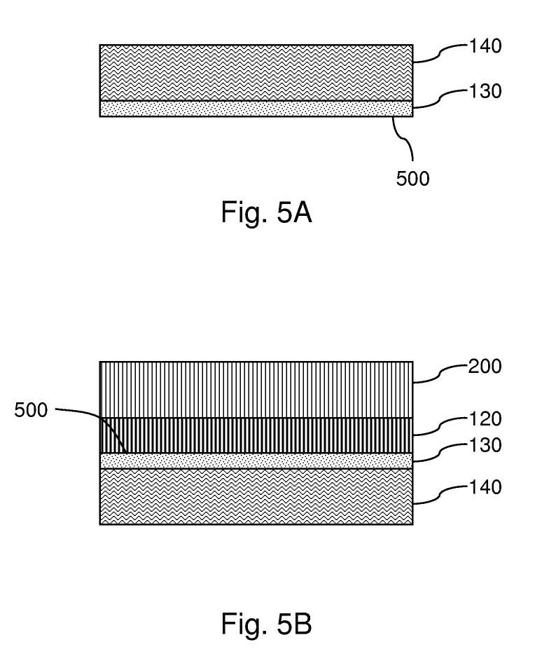

In an embodiment, referring back to FIG. 1A, diffusion barrier 130 may be formed epitaxially on buffer layer 120, thus inheriting the texture of buffer layer 120 (and textured template 100). For example, diffusion barrier 130 may include or consist essentially of textured epitaxial W. W that is deposited cold on a non-lattice matched surface tends to form a mixed crystalline structure that generally precludes epitaxial growth. However, the presence of a lattice-matched template such as a buffer layer 120 including or consisting essentially of Cr allows W to be deposited epitaxially at relatively low temperatures, as low as approximately 300° C. Substrate layer 140 preferably is substantially free of the texture of buffer layer 120 (and textured template 100). Referring to FIGS. 5A and 5B, buffer layer 120 may then be removed during the removal of textured template 100 and sacrificial layer 110, thus exposing surface 155. Semiconductor layer 200 may then be formed on surface 500, or, as shown in FIG. 5B, another buffer layer 120 may be formed on surface 500, followed by the formation of semiconductor layer 200. Preferably the formation of this buffer layer 120 and semiconductor layer 200 are performed concurrently without any intervening exposure to oxygen in order to prevent oxidation of buffer layer 120 and facilitate the high-quality formation of semiconductor layer 200.

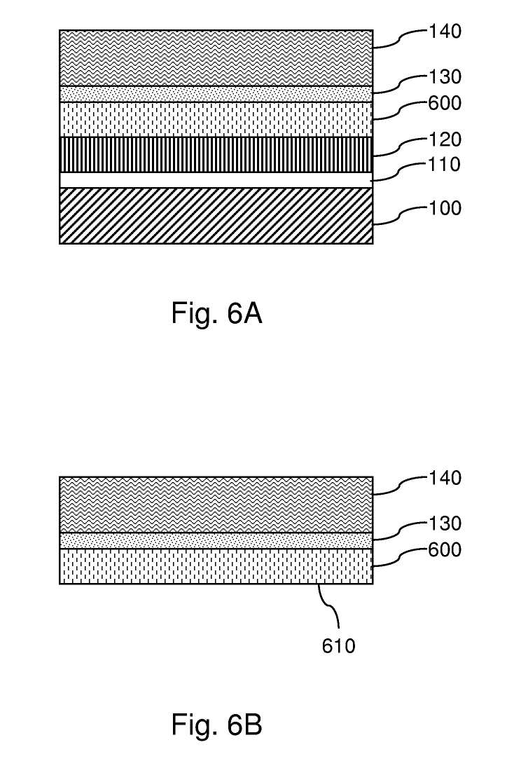

In another embodiment, buffer layer 120 including or consisting essentially of Cr is supplemented with a layer having greater resistance to oxidation. For example, referring to FIG. 6A, oxidation-resistant layer 600 may be formed between buffer layer 120 and diffusion barrier 130. Oxidation-resistant layer 600 may be formed by deposition, e.g., evaporation, sputtering, chemical vapor deposition, atomic layer deposition, molecular beam epitaxy, metallorganic deposition, or by electrochemical means such as electroplating (with or without electrodes). During formation, oxidation-resistant layer 600 inherits the texture of buffer layer 120 and textured template 100. Oxidation-resistant layer 600 may be provided without ion-beam assistance. Oxidation-resistant layer 600 preferably has a larger (i.e., less negative) free energy of oxide formation than Cr. In an embodiment, oxidation-resistant layer 600 includes or consists essentially of a noble metal such as Pd, Rh, Pt, or Ir.

Referring to FIG. 6B, buffer layer 120 is removed during the removal of textured template 100 and sacrificial layer 110, thus exposing surface 610 of oxidation-resistant layer 600. Surface 610 is preferably at least substantially oxide-free (i.e., while oxygen may be present on surface 610 in small amounts (e.g., fractions of a monolayer), any oxide present does not coat the entirety of surface 610). As described above with reference to FIG. 2, semiconductor layer 200 may be formed directly on surface 610. In another embodiment, a buffer layer 120 may be formed on surface 610 prior to formation of semiconductor layer 200. In cases in which oxidation-resistant layer 600 has a low melting point (indicating, e.g., potentially high diffusivity thereof in a subsequently formed semiconductor layer 200), the formation of a new buffer layer 120 prior to formation of semiconductor layer 200 may prevent interdiffusion of oxidation-resistant layer 600 and semiconductor layer 200.

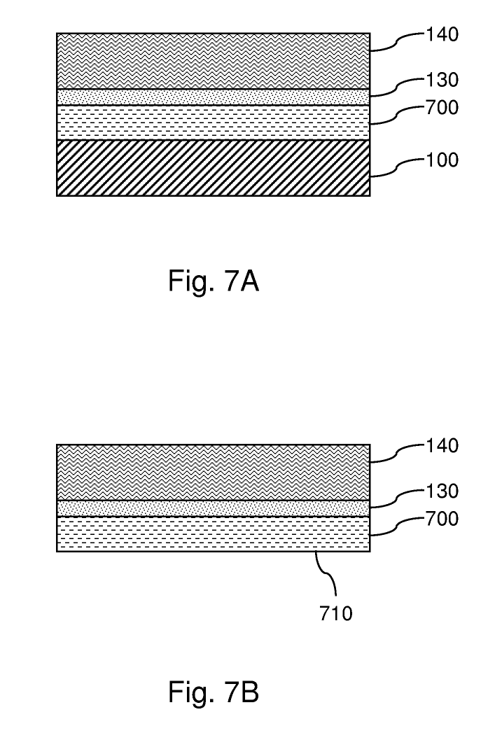

Referring to FIG. 7A, in certain embodiments, sacrificial layer 110 may be omitted, and buffer layer 120 is replaced with etch-stop layer 700. Etch-stop layer 700 may be formed by deposition, e.g., evaporation, sputtering, chemical vapor deposition, atomic layer deposition, molecular beam epitaxy, metallorganic deposition, or by electrochemical means such as electroplating (with or without electrodes). During formation, etch-stop layer 700 inherits the texture of textured template 100. Etch-stop layer 700 may be provided without ion-beam assistance, and may include or consist essentially of an oxidation-resistant material (e.g., a noble metal such as Pd or iridium (Ir)) or an epitaxial insulator (e.g., an epitaxial oxide such as strontium oxide or magnesium oxide, or TiN or TaN). Etch-stop layer 700 preferably does not easily alloy with textured template 100 (e.g., does not form solid alloys with metals such as Cu or Ni), thus enabling selective removal of textured template 100. Etch-stop layer 700 also preferably has a high melting point (e.g., greater than approximately 1200° C.) and substantially does not interdiffuse with textured template 100, thus facilitating selective removal of textured template 100 with substantially no impact (e.g., damage or surface modification) on etch-stop layer 700. Referring to FIG. 7B, textured template 100 is removed, thus exposing surface 710 of etch-stop layer 700. As described above with reference to FIG. 6B, a semiconductor layer 200 may be formed over surface 710, with or without the formation of a buffer layer 120 on surface 710 prior to formation of semiconductor layer 200.

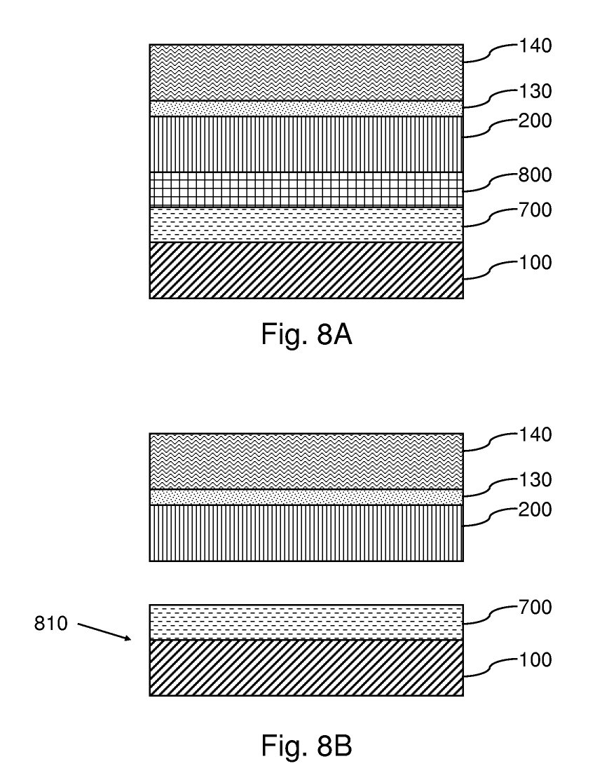

Referring to FIG. 8A, the use of a lift-off process may facilitate the removal of certain layers, and may enable the formation of semiconductor layer 200 prior to the removal of textured template 100. Etch-stop layer 700 is formed atop textured template 100, and then a lift-off layer 800 is formed thereover. Lift-off layer 800 may be polycrystalline, and may be formed by deposition, e.g., evaporation, sputtering, chemical vapor deposition, atomic layer deposition, molecular beam epitaxy, metallorganic deposition, or by electrochemical means such as electroplating (with or without electrodes). During formation, lift-off layer 800 inherits the texture of textured template 100. Lift-off layer 800 may be provided without ion-beam assistance, and may include or consist essentially of a water-soluble material. In an embodiment, lift-off layer 800 includes or consists essentially of an ionic salt such as calcium fluoride (CaF₂) or sodium chloride (NaCl). Semiconductor layer 200 is formed over lift-off layer 200, preferably at a low temperature. Diffusion barrier 130 and substrate layer 140 are then formed over semiconductor layer 200.

Referring to FIG. 8B, lift-off layer 800 is removed by, e.g., application of water or an organic solvent, leaving semiconductor layer 200 on diffusion barrier 130 and substrate layer 140. One or more semiconductor devices (such as semiconductor devices 300 and/or 400 described above) may be fabricated on semiconductor layer 200. The portion 810 including etch-stop layer 700 and textured template 100 may remain at least substantially intact, and may be reused (e.g., by the deposition of new lift-off layers 800 and/or semiconductor layers 200, etc.).

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1-27. (canceled)

28. A method for forming a semiconductor device, the method comprising:
providing a textured template;
forming a buffer layer over the textured template, the buffer layer inheriting a texture of the textured template;
forming an oxidation-resistant layer over the buffer layer, the oxidation-resistant layer inheriting the texture of the textured template;
forming a substrate layer over the oxidation-resistant layer;
removing the textured template and the buffer layer, thereby exposing a surface of the oxidation-resistant layer; and
forming a semiconductor layer over the exposed surface of the oxidation-resistant layer.

29. The method of claim 28, further comprising forming a second buffer layer over the exposed surface of the oxidation-resistant layer prior to forming the semiconductor layer, the second buffer layer inheriting the texture of the textured template.

30-31. (canceled)

32. The method of claim 28, wherein the oxidation-resistant layer comprises at least one noble metal.

33-34. (canceled)

35. The method of claim 28, wherein the semiconductor layer comprises at least one of Si, Ge, or a III-V material.

36. The method of claim 28, wherein a coefficient of thermal expansion of the substrate layer substantially matches a coefficient of thermal expansion of the semiconductor layer.

37-42. (canceled)

43. A method for forming a semiconductor device, the method comprising:
providing a textured template;
forming an etch-stop layer over the textured template, the etch-stop layer inheriting a texture of the textured template;
forming a diffusion barrier over the etch-stop layer;
forming a substrate layer over the diffusion barrier;
removing the textured template, thereby exposing a surface of the etch-stop layer; and
forming a semiconductor layer over the exposed surface of the etch-stop layer.

44. The method of claim 43, wherein the etch-stop layer comprises a noble metal.

45. (canceled)

46. The method of claim 43, wherein the etch-stop layer comprises an epitaxial oxide.

47. The method of claim 43, further comprising forming a buffer layer over the exposed surface of the etch-stop layer prior to forming the semiconductor layer, the buffer layer inheriting the texture of the textured template.

48. (canceled)

49. The method of claim 43, wherein the semiconductor layer comprises at least one of Si, Ge, or InGaAs.

50. The method of claim 43, wherein a coefficient of thermal expansion of the substrate layer substantially matches a coefficient of thermal expansion of the semiconductor layer.

51. The method of claim 43, wherein the diffusion barrier comprises W.

52-72. (canceled)

73. A semiconductor structure comprising:
a substantially untextured substrate layer;
a textured diffusion barrier disposed over the substrate layer;
a textured buffer layer disposed over the textured diffusion barrier; and
a semiconductor layer disposed over the textured buffer layer.

74. The semiconductor structure of claim 73, wherein a grain size of the textured buffer layer is greater than approximately 25 μm.

75. The semiconductor structure of claim 73, wherein the textured buffer layer comprises a metal or a metal alloy.

76. (canceled)

77. The semiconductor structure of claim 73, wherein the textured diffusion barrier comprises a metal or a metal alloy.

78. The semiconductor structure of claim 77, wherein the textured diffusion barrier comprises at least one of W or Re.

79. The semiconductor structure of claim 77, wherein the substrate layer comprises at least one of W, Mo, a metal alloy, a ceramic, or a glass.

80. The semiconductor structure of claim 77, wherein a coefficient of thermal expansion of the substrate layer substantially matches a coefficient of thermal expansion of the semiconductor layer.

81-82. (canceled)

83. The semiconductor structure of claim 73, wherein the semiconductor layer comprises at least one of GaAs, AlGaAs, InGaP, InGaAsN, InGaAsP, InP, AlInAs, or InGaAs.

84-100. (canceled)

101. A structure comprising:
a textured template comprising a first metal;
an etch-stop layer disposed over the textured template, the etch-stop layer comprising at least one of an oxide or a second metal different from the first metal; and
a substantially untextured substrate layer disposed over the etch-stop layer, the substrate layer comprising at least one of a ceramic, a glass, or a third metal different from both the first and second metals,
wherein there is substantially no interdiffusion between the textured template and the etch-stop layer.

102. The structure of claim 101, wherein the etch-stop layer comprises a noble metal.

103. (canceled)

104. The structure of claim 101, wherein a texture of the etch-stop layer substantially matches the texture of the textured template.

105-118. (canceled)
